(19) United States
(12) Patent Application Publication
(10) Pub. No.: US 2008/0186678 A1
(43) Pub. Date: Aug. 7, 2008

(54) Nanoparticle Enhanced Heat Conduction Apparatus

(75) Inventors: Travis North, Pflugerville, TX (US); Michael Mincen Heatly, Round Rock, TX (US)

Correspondence Address: HAYNES AND BOONE, LLP, 901 Main Street, Suite 3100, Dallas, TX, 75202, US

(73) Assignee: DELL PRODUCTS L.P., Round Rock, TX (US)

(21) Appl. No.: 11/671,743

(22) Filed: Feb. 6, 2007

(51) Int. Cl. H05K 7/20

(52) U.S. Cl. 361/700; 361/699

(57) ABSTRACT

A heat conduction apparatus includes a sealed body having an inside surface and defining a cavity. A capillary structure is on the inside surface of the sealed body. A working fluid is in the cavity and includes nanoparticles. The heat conduction apparatus may be coupled to a heat producing component in order to provide greater heat dissipation capability than is provided by a heat conduction apparatus with a conventional working fluid.

### BACKGROUND

The present disclosure relates generally to information handling systems, and more particularly to providing heat conduction for an information handling system by utilizing a working fluid including nanoparticles.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

As the performance and operating frequency requirements of IHSs increase and the size of IHS chassis decrease, there has been a dramatic increase in the heat generation density within the IHS chassis. This may cause IHS performance issues such as, for example, component failure due to overheating. As such, there is a need to dissipate the heat generated by components in the IHS chassis in order to achieve better performance of the components and the IHS, as well as to increase the lifespan of both. This dissipation can allow for enhanced IHS quality, increased design margin, and a better IHS user experience.

Dissipation of the heat generated by a component in the IHS chassis may be accomplished by thermally coupling a heat conduction apparatus to the component. A heat conduction apparatus often includes passive devices such as, for example, heatpipes, vapor chambers, and/or thermosyphons. However, the limited heat transfer capability of the conventional forms of these apparatus can result in a decrease in IHS or component performance, or require that a greater number of the heat conduction apparatus be used in order to achieve adequate performance, which can increase costs and use more of the housing volume in the IHS chassis than is desirable. In addition, providing a greater quantity of heat conduction apparatus increases the IHS manufacturer's challenges with sourcing a supply of such apparatus.

Accordingly, it would be desirable to provide for heat conduction with enhanced heat transfer capability absent the disadvantages discussed above.

### SUMMARY

According to one embodiment, a heat conduction apparatus includes a sealed body having an inside surface and defining a cavity, a capillary structure on the inside surface of the sealed body, and a working fluid in the cavity, wherein the working fluid comprises nanoparticles.

### BRIEF DESCRIPTION OF THE DRAWINGS

FIG. 1 is a schematic view illustrating an embodiment of an IHS.

FIG. 2 is a perspective view illustrating an embodiment of an IHS chassis including a heat generating component and a heat conduction apparatus.

FIG. 3a is a cross-sectional perspective view illustrating an embodiment of the heat conduction apparatus of FIG. 2.

FIG. 3b is a schematic view illustrating an embodiment of the working fluid of the heat conduction apparatus of FIG. 3a.

FIG. 4a is a schematic view illustrating an alternate embodiment of the heat conduction apparatus of FIG. 2.

FIG. 4b is a schematic view illustrating an embodiment of the working fluid of the heat conduction apparatus of FIG. 4a.

FIG. 5a is a schematic view illustrating an alternate embodiment of the heat conduction apparatus of FIG. 2.

FIG. 5b is a schematic view illustrating an embodiment of the working fluid of the heat conduction apparatus of FIG. 5a.

FIG. 6a is a schematic view illustrating an embodiment of a cross-section of the heat conduction apparatus of FIG. 5a.

FIG. 6b is a schematic view illustrating an alternate embodiment of a cross-section of the heat conduction apparatus of FIG. 5a.

FIG. 6c is a schematic view illustrating an alternate embodiment of a cross-section of the heat conduction apparatus of FIG. 5a.

FIG. 7 is a flow chart illustrating an embodiment of a method of dissipating heat from a heat generating component using a heat conduction apparatus.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU), or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

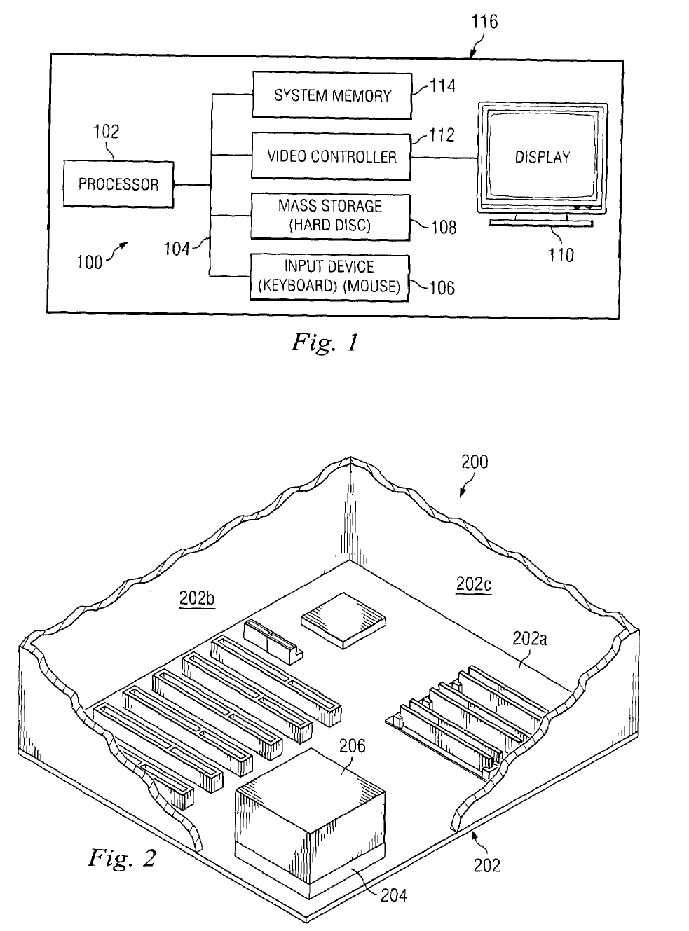

In one embodiment, IHS 100, FIG. 1, includes a processor 102, which is connected to a bus 104. Bus 104 serves as a connection between processor 102 and other components of computer system 100. An input device 106 is coupled to processor 102 to provide input to processor 102. Examples of input devices include keyboards, touchscreens, and pointing devices such as mouses, trackballs, and trackpads. Programs and data are stored on a mass storage device 108, which is coupled to processor 102. Mass storage devices include such devices as hard disks, optical disks, magneto-optical drives, floppy drives and the like. IHS 100 further includes a display 110, which is coupled to processor 102 by a video controller 112. A system memory 114 is coupled to processor 102 to provide the processor with fast storage to facilitate execution of computer programs by processor 102. In an embodiment, a chassis 116 houses some or all of the components of IHS 100. It should be understood that other buses and intermediate circuits can be deployed between the components described above and processor 102 to facilitate interconnection between the components and the processor 102.

Referring now to FIG. 2, an IHS chassis 200 is illustrated. In an embodiment, the IHS chassis 200 may be, for example, the IHS chassis 116 described above with reference to FIG. 1 and may house some or all of the components of the IHS 100, also described above with reference to FIG. 1. The IHS chassis 200 includes a base 202 having a chassis floor 202a and a pair of chassis walls 202b and 202c extending from the chassis floor 202a in a substantially perpendicular orientation to the chassis floor 202a and each other. A heat generating component 204 is mounted to the chassis floor 202a. In an embodiment, the heat generating component may be, for example, the processor 102, described above with reference to FIG. 1. A heat conduction apparatus 206 is thermally coupled to the heat generating component 204. In an embodiment, the heat conduction apparatus 206 is coupled to a top surface of the heat generating component 204. In an embodiment, the heat conduction apparatus 206 may further include, for example, active devices (e.g. fans), heat sinks, finned heat sinks, cold plates, or a variety of other heat conduction devices as known in the art.

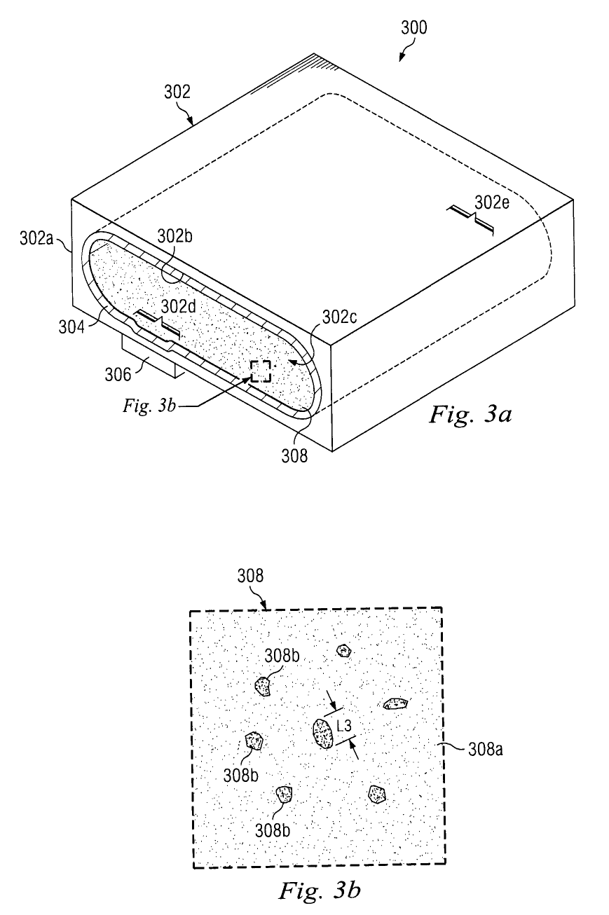

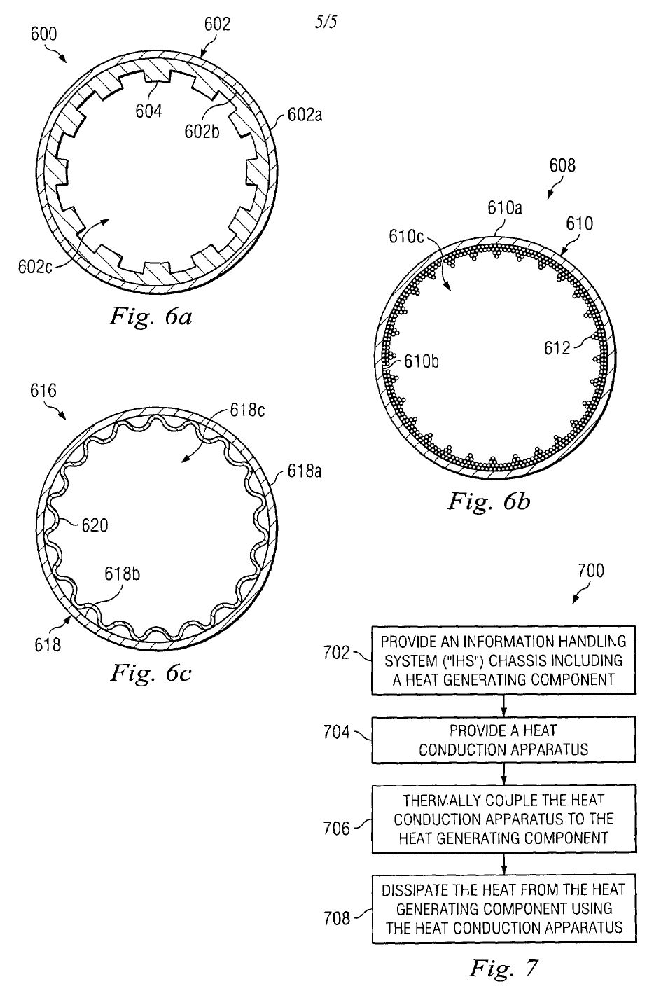

Referring now to FIGS. 3a and 3b, a vapor chamber 300 is illustrated. In an embodiment, the vapor chamber 300 may be included in the heat conduction apparatus 206, described above with reference to FIG. 2. The vapor chamber 300 includes a body 302 having an outside surface 302a, an inside surface 302b located opposite the outside surface 302a, and a cavity 302c defined by the body 302 and located adjacent the inside surface 302b. In an embodiment, the body 302 is copper, stainless steel, or aluminum. In an embodiment, the cavity 302c is at least partially evacuated and the body 302 is sealed, creating a closed system in order to maintain a pressure within the cavity 302c. A capillary structure 304 is located on the inside surface 302b. A working fluid 308 is located within the cavity 302c. The working fluid 308 includes a fluid 308a and nanoparticles 308b suspended in the fluid 308a. In an embodiment, the fluid 308a includes primarily water. In an embodiment, the nanoparticles 308b include metal particles. In an embodiment, the nanoparticles 308b are copper particles, gold thiolate particles, and/or aluminum oxide particles. In an embodiment, the size L3 of the nanoparticles 308b is approximately 10 to 60 nanometers. Because of their size, the nanoparticles 308b do not settle in the fluid 308a and the electrical charges of the nanoparticles 308b allow for the formation of a stable suspension in which the nanoparticles 308b are evenly distributed throughout the fluid 308a. In an embodiment, the working fluid 308 includes approximately 5% or less nanoparticles by volume. In an embodiment, the working fluid 308 includes approximately 4% nanoparticles by volume. The working fluid 308 has a higher thermal conductivity relative to a conventional working fluid, such as, for example, water. In an embodiment, a heat generating component 306 is coupled to the vapor chamber 300 through the engagement of the heat generating component 306 and the outside surface 302a such that an evaporating region 302d and a condensing region 302e are created. In an embodiment, the heat generating component 306 may be the heat generating component 204, described above with reference to FIG. 2. In an embodiment, a heat sink is thermally coupled to the vapor chamber 300 adjacent the condensing region 302e. The capillary structure 304 material and structure is chosen such that it is operable to move the working fluid 308 within the vapor chamber 300 from the condensing region 302e to the evaporating region 302d using capillary forces. In an embodiment, the capillary structure 304 is a sintered particle structure, a grooved structure, and/or a mesh structure, discussed below with reference to FIGS. 6a, 6b and 6c.

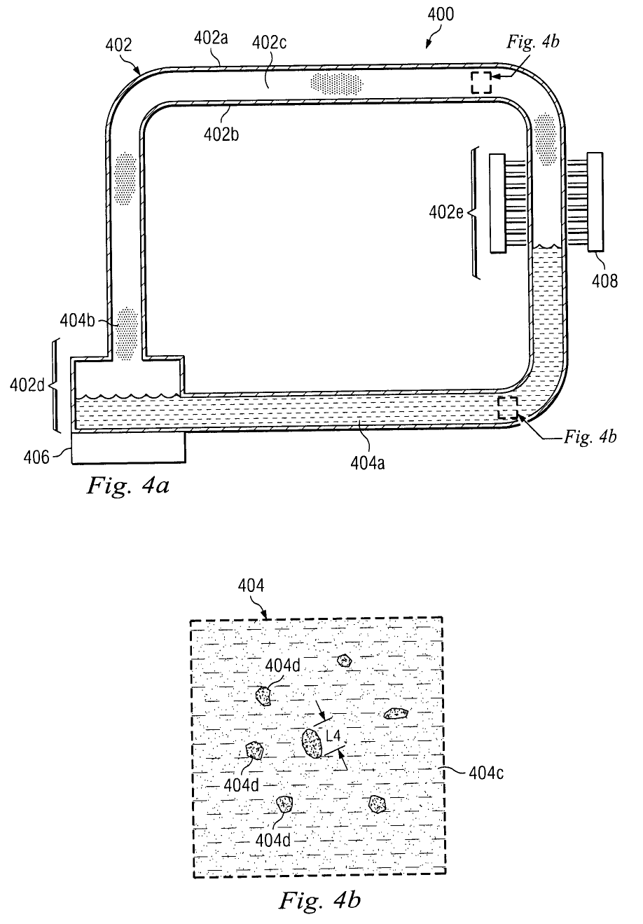

Referring now to FIG. 4a, a thermosyphon 400 is illustrated. In an embodiment, the thermosyphon 400 may be included in the heat conduction apparatus 206, described above with reference to FIG. 2. The thermosyphon 400 includes a body 402 having a first wall 402a, a second wall 402b located opposite the first wall 402a, and a cavity 402c defined by the body 402 and located between the first wall 402a and the second wall 402b. The cavity 402c is at least partially evacuated and the body 402 sealed, creating a closed system. In an embodiment, the body 402 is copper, stainless steel, or aluminum. A working fluid 404, illustrated in FIG. 4b, includes a liquid phase 404a and a vapor phase 404b and is contained in the cavity 402c. The working fluid 404 includes a fluid 404c and nanoparticles 404d suspended in the fluid 404c. In an embodiment, the fluid 404c includes primarily water. In an embodiment, the nanoparticles 404d include metal particles. In an embodiment, the nanoparticles 404d are copper particles, gold thiolate particles, and/or aluminum oxide particles. In an embodiment, the size L4 of the nanoparticles 404d is approximately 10 to 60 nanometers. Because of their size, the nanoparticles 404d do not settle in the fluid 404c and the electrical charges of the nanoparticles 404d allow for the formation of a stable suspension in which the nanoparticles 404d are evenly distributed throughout the fluid 404c. In an embodiment, the working fluid 404 includes approximately 5% or less nanoparticles by volume. In an embodiment, the working fluid 404 includes approximately 4% nanoparticles by volume. The working fluid 404 has a higher thermal conductivity relative to a conventional working fluid, such as, for example, water. In an embodiment, a heat generating component 406 and a finned heat sink 408 are thermally coupled to the body 402 creating an evaporating region 402d and a condensing region 402e. In an embodiment, the heat generating component 406 may be the heat generating component 204, described above with reference to FIG. 2. In an embodiment, a finned heat sink 408 may include a heat sink, cold plate, fan, or other heat conduction apparatus as known in the art. In an embodiment, the working fluid 404 is contained in a thermosyphon that includes other geometries such as, for example, a bundle of sealed tubes, and/or other thermosyphon geometries as known in the art.

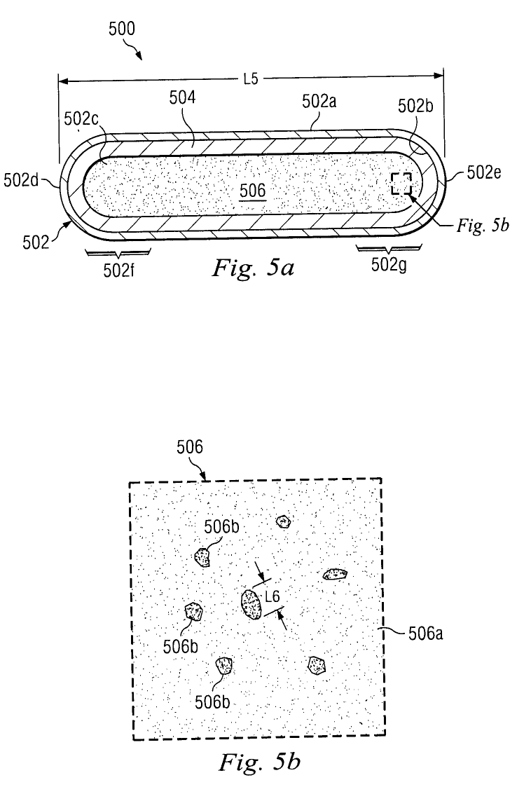

Referring now to FIG. 5, a heatpipe 500 is illustrated. In an embodiment, the heatpipe 500 may be included in the heat conduction apparatus 206, described above with reference to FIG. 2. The heatpipe 500 includes a body 502 having an outside surface 502a, an inside surface 502b located opposite the outside surface 502a, a cavity 502c defined by the body 502 and located adjacent the inside surface 502b, a first end 502d, and a second end 502e located opposite the first end 502d. In the illustrated embodiment, the body 502 is tubular in shape. In an embodiment, the heatpipe 500 has a length L5, which is the distance between the first end 502d and the second end 502e, of approximately 6 mm. In an embodiment, the heatpipe 500 has a length L5 of approximately 8 mm. In an embodiment, the body 502 is copper, stainless steel, or aluminum. In an embodiment, the cavity 502c is at least partially evacuated and the body 502 is sealed, creating a closed system in order to maintain a pressure within the cavity 302c. A capillary structure 504 is located on the inside surface 502b. A working fluid 506, illustrated in FIG. 5b, is located in the cavity 502c. The working fluid 506 includes a fluid 506a and nanoparticles 506b suspended in the fluid 506a. In an embodiment, the fluid 506a includes primarily water. In an embodiment, the nanoparticles 506b include metal particles. In an embodiment, the nanoparticles 506b are copper particles, gold thiolate particles, and/or aluminum oxide particles. In an embodiment, the size L6 of the nanoparticles 506b is approximately 10 to 60 nanometers. Because of their size, the nanoparticles 506b do not settle in the fluid 506a and the electrical charges of the nanoparticles 506b allow the formation of a stable suspension in which the nanoparticles 506b are evenly distributed throughout the fluid 506a. In an embodiment, the working fluid 506 includes approximately 5% or fewer nanoparticles by volume. In an embodiment, the working fluid 506 includes approximately 4% nanoparticles by volume. The working fluid 506 has an increased thermal conductivity relative to a conventional working fluid, such as, for example, water. In an embodiment, the first end 502d is located adjacent a heat generating component and the second end 502e is located adjacent a heat sink such that the first end 502d is at a higher temperature and the second end 502e is at a lower temperature and an evaporating region 502f and a condensing region 502g are created. The capillary structure 504 is chosen such that it is operable to move the working fluid 506 within the heatpipe 500 from the condensing region 502g to the evaporating region 502f using capillary forces. In an embodiment, the capillary structure 504 is a sintered particle structure, a grooved structure, and/or a mesh structure, discussed below with reference to FIGS. 6a, 6b and 6c. In an embodiment, the working fluid 506 is contained in a heatpipe that includes other geometries, such as, for example, flat pipes, known in the art, as the presence of a capillary structure alleviates the need to rely on gravity for functionality.

Referring now to FIGS. 6a, 6b and 6c, embodiments of capillary structures are illustrated. FIG. 6a illustrates a heatpipe 600 including a body 602 having an outside surface 602a, an inside surface 602b located opposite the outside surface 602a, and a cavity 602c defined by the body 602 and located adjacent the inside surface 602b. A grooved capillary structure 604 is located on the inside surface 602b. In an embodiment, the grooved capillary structure 604 is fabricated by etching grooves into the inside surface 602b of the body 602. FIG. 6b illustrates a heatpipe 608 including a body 610 having an outside surface 610a, an inside surface 610b located opposite the outside surface 610a, and a cavity 610c defined by the body 610 and located adjacent to the inside surface 610b. A sintered particle capillary structure 612 is located on the inside surface 610b. In an embodiment, the sintered particle capillary structure 612 is fabricated by molding and heating metal powder until a structurally stable metal with small pores fused to the inside surface 610b of the body 610 is created. FIG. 6c illustrates a heatpipe 616 including a body 618 having an outside surface 618a, an inside surface 618b located opposite the outside surface 618a, and a cavity 618c defined by the body 618 and located adjacent to the inside surface 618b. A mesh capillary structure 620, also known as a screen mesh structure, is located on the inside surface 618b of the body 618. In an embodiment, the capillary structures 604, 612 and 620 may be steel, aluminum, nickel, copper, or ceramic. In an embodiment, a variety of capillary structures may be combined within one heat conduction apparatus, such as, for example, the grooved capillary structure 604 described above with reference to FIG. 6a, and the mesh capillary structure 620, described above with reference to FIG. 6c. In an embodiment, the capillary structures 604, 612 and 620 may be included in the vapor chamber 300 as the capillary structure 304, described above with reference to FIG. 3. In an embodiment, the capillary structures 604, 612 and 620 may be included in the heatpipe 500 as the capillary structure 504, described above with reference to FIG. 5.

Referring now to FIG. 7, a method 700 of dissipating heat from a heat generating component in an IHS chassis is illustrated. The method 700 begins with step 702 where an IHS chassis and heat generating component, such as, for example, the IHS chassis 200 and the heat generating component 204, described above with reference to FIG. 2, are provided. The method 700 then proceeds to step 704 where a heat conduction apparatus is provided. In an embodiment, the heat conduction apparatus provided may be the vapor chamber 300 including the working fluid 308, described above with reference to FIGS. 3a and 3b, the thermosyphon 400 including the working fluid 404, described above with reference to FIGS. 4a and 4b, or the heatpipe 500 including the working fluid 506, described above with reference to FIGS. 5a and 5b. The method 800 continues to step 806 where the heat conduction apparatus is thermally coupled to the heat generating component. This coupling may be, for example, as shown in FIG. 2. The method 800 completes with step 808 where the operation of the heat conduction apparatus dissipates heat from the heat generating component in the IHS. The dissipation is accomplished by the evaporation and condensation of the working fluid contained within heat conduction apparatus.

Referring now to FIGS. 5a, 5b and 7, in an embodiment of the method 700, the heat conduction apparatus provided in step 704 is the heatpipe 500 including the working fluid 506, described above with reference to FIGS. 5a and 5b. In step 706, the heatpipe 500 is thermally coupled at the first end 502d to the heat generating component provided in step 702. The working fluid 506, located in the cavity 502c in the evaporating region 502f, evaporates and transfers energy in the form of heat from the heat generating component's immediate environment. The working fluid 506, now in a vapor phase, flows toward the second end 502d of the heatpipe 500 to the condensing region 502g where it condenses, the energy being transferred back to the environment away from the heat generating component. The condensed working fluid 506 then flows back to the evaporating region 502f, partially by means of the capillary structure 504. The working fluid 506 again evaporates and the process is repeated and the heat is continually dissipated from the heat generating component's immediate environment. More heat is dissipated using the working fluid 506 relative to using a conventional working fluid as the thermal conductivity of the working fluid 506 is greater than that of a conventional working fluid. The heatpipe 500 functions by the pool boiling effect (i.e. the evaporation of the liquid working fluid in the evaporating region 502f) and a change in thermal conductivity of the working fluid affects the overall capabilities of the heatpipe. The pool boiling effect is limited by the thermal conductivity of the working fluid so that an increase in thermal conductivity, and thus the maximum heat transfer capabilities of the working fluid, may lead to an increase in the heat transfer capabilities of the heatpipe 500 among other benefits such as, for example, lowering the operating temperature of the heatpipe 500.

Referring now to FIGS. 3a, 3b and 7, in an embodiment of the method 700, the heat conduction apparatus provided in step 704 is the vapor chamber 300 including the working fluid 308, described above with reference to FIGS. 3a and 3b. The dissipation of heat from the heat generating component in step 706 is accomplished in substantially the same manner as described above with regard to the description of the embodiment of the method 700 including the heatpipe 500. As the vapor chamber 300 also functions by the pool boiling effect, the use of the working fluid 308 may lead to an increase in the heat transfer capabilities of the vapor chamber 300.

Referring now to FIGS. 4a, 4b and 7, in an embodiment of the method 700, the heat conduction apparatus provided in step 704 is the thermosyphon 400 with working fluid 404, described above with reference to FIGS. 4a and 4b. The dissipation of heat from the heat generating component in step 706 is accomplished in much the same manner as detailed above with regard to the description of the embodiment of the method 700 including the heatpipe 500 except that the condensed working fluid 404 is returned to the evaporating region 402d by gravity. As the thermosyphon 400 also functions by the pool boiling effect, the use of the working fluid 404 may lead to an increase in the heat transfer capabilities of the thermosyphon 400. In an embodiment, the enhanced fluid 308, 404, 506 may be used as the working fluid in a variety of other heat conduction apparatus, as known in the art, also increasing the dissipation of heat relative to the use of a conventional working fluid. Thus, a heat conduction apparatus containing a working fluid including nanoparticles is provided that allows for additional heat dissipation relative to a heat conduction apparatus containing a conventional working fluid.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A heat conduction apparatus, comprising:
a sealed body having an inside surface and defining a cavity;
a capillary structure on the inside surface of the sealed body; and
a working fluid in the cavity, wherein the working fluid comprises nanoparticles.

2. The apparatus of claim 1, wherein the capillary structure comprises a mesh structure.

3. The apparatus of claim 1, wherein the capillary structure comprises a grooved structure.

4. The apparatus of claim 1, wherein the capillary structure comprises a sintered particle structure.

5. The apparatus of claim 1, wherein the working fluid comprises approximately 4% nanoparticles by volume.

6. The apparatus of claim 1, wherein the nanoparticles comprise metal particles.

7. The apparatus of claim 6, wherein the nanoparticles are chosen from the group consisting of gold thiolate, copper, and aluminum oxide.

8. The apparatus of claim 1, wherein the nanoparticles range in size from approximately 10 to 60 nanometers.

9. The apparatus of claim 1, wherein the sealed body comprises a heatpipe.

10. The apparatus of claim 1, wherein the sealed body comprises a vapor chamber.

11. An information handling system, comprising:
a chassis;
a processor mounted in the chassis; and
a heat conduction apparatus thermally coupled to the processor, the heat conduction apparatus comprising:
a sealed body having an inside surface and defining a cavity;
a capillary structure on the inside surface of the sealed body; and
a working fluid in the cavity, wherein the working fluid comprises nanoparticles.

12. The system of claim 11, wherein the capillary structure comprises a mesh structure.

13. The system of claim 11, wherein the capillary structure comprises a grooved structure.

14. The system of claim 11, wherein the capillary structure comprises a sintered particle structure.

15. The system of claim 11, wherein the nanoparticles comprise metal particles.

16. The system of claim 15, wherein the nanoparticles are chosen from the group consisting of gold thiolate, aluminum oxide, and copper.

17. The system of claim 11, wherein the working fluid comprises approximately 4% nanoparticles by volume.

18. The system of claim 11, wherein the sealed body comprises a heatpipe.

19. A method of dissipating heat from a heat generating component comprising:
providing a heat conduction apparatus thermally coupled to the heat generating component and comprising a sealed body defining a cavity and including an inside surface having a capillary structure, wherein a fluid including nanoparticles is in the cavity;
thermally coupling the heat conduction apparatus to the heat generating component; and
dissipating heat from the heat generating component with the fluid.

20. The method of claim 19, wherein the dissipating comprises circulating the fluid using the capillary structure.
